(19) United States
(12) Patent Application Publication
(10) Pub. No.: US 2020/0328197 A1
(43) Pub. Date: Oct. 15, 2020

(54) DISPLAY APPARATUS AND METHOD OF MANUFACTURING THEREOF

(71) Applicant: SAMSUNG ELECTRONICS CO., LTD., Suwon-si (KR)

(72) Inventors: Seungryong Han, Suwon-si (KR); Hyunsun Kim, Suwon-si (KR); llju Mun, Suwon-si (KR)

(73) Assignee: SAMSUNG ELECTRONICS CO., LTD., Suwon-si (KR)

(21) Appl. No.: 16/845,712

(22) Filed: Apr. 10, 2020

(30) Foreign Application Priority Data
Apr. 12, 2019 (KR) 10-2019-0043210

(51) Int. Cl. H01L 25/16; H01L 33/52; H01L 33/58; H01L 33/62; H01L 23/00

(52) U.S. Cl. CPC H01L 25/167; H01L 33/52; H01L 33/58; H01L 33/62; H01L 24/11; H01L 2924/12041; H01L 24/81; H01L 2933/0066; H01L 2933/005; H01L 2933/0058; H01L 2224/16145; H01L 24/13

(57) ABSTRACT

A display apparatus includes a substrate on which a driving circuit is formed; an inorganic light emitting device that is formed on the driving circuit and included in a pixel from among a plurality of pixels of the display apparatus; an absorber that is formed between the inorganic light emitting device and another inorganic light emitting device included in the pixel, the absorber configured to absorb an external light; and a textured transparent resin formed On the inorganic light emitting device.

### CROSS-REFERENCE TO THE RELATED APPLICATION

This application is based on and claims priority under 35 U.S.C. § 119 to Korean Patent Application No. 10-2019-0043210, filed on Apr. 12, 2019, in the Korean Intellectual Property Office, the disclosure of which is incorporated by reference herein in its entirety.

### BACKGROUND

### Field

Embodiments of the disclosure relate to a display apparatus and a manufacturing method thereof and, more particularly, to a display apparatus with improved light efficiency and a manufacturing method thereof.

### Description of Related Art

A light emitting diode (LED) is a semiconductor device that emits light when a voltage is applied, and is widely used as a light source of a display apparatus for displaying an image as well as a general lighting device. Recently, a display apparatus using a micro-LED (μ-LED) as a light source has been developed.

A display panel to which a micro LED (Micro LED, mLED, or μLED) is applied is one of a flat display panel and is formed of a plurality of inorganic LEDs, each of which is 100 micrometers or less. A micro LED display panel provides better contrast, response time and energy efficiency compared to a liquid crystal display (LCD) panel in which a backlight is required. Both the organic LED (OLED) and the micro LED have good energy efficiency, but the micro LED has better brightness and light-emitting efficiency and a longer life span than that of the OLED.

In that the micro LED emits light using an inorganic material, the micro LED has a low burn-in phenomenon, has a long life span, is easy to be manufactured as a large-sized or user-customized display panel through a tiling arrangement of module units, and may be driven at low power with little heat generation due to a short current path.

The micro LED may be individually driven as a pixel unit (or a sub-pixel unit forming a pixel) forming an image wherein the micro LED is an ultra-small self-light emitting device. For this purpose, in a high-resolution display apparatus, it is required that the size of the micro LED is reduced and the distance between the micro LEDs (that is, a pitch) is reduced. For example, about 2 million micro LEDs may be required for a display apparatus of the UHD specification (3840×2160 in number of pixels).

An LED emits non-directional light, and the micro LED has a problem that it is difficult to refract (or reflect) light emitted in a lateral direction inside the device due to the miniaturization, spatial, or structural constraints of the device, unlike a general LED. Accordingly, there is a problem in that the optical efficiency is degraded.

### SUMMARY

According to one or more embodiments, a display apparatus includes: a substrate on which a driving circuit is formed; an inorganic light emitting device that is formed on the driving circuit and included in a pixel from among a plurality of pixels of the display apparatus; an absorber that is formed between the inorganic light emitting device and another inorganic light emitting device included in the pixel, the absorber configured to absorb an external light; and a textured transparent resin formed on the inorganic light emitting device.

According to an embodiment, a size of the textured transparent resin is greater than or equal to a size of an upper surface of the inorganic light emitting device through which light emitted from the inorganic light emitting device passes.

According to an embodiment, the textured transparent resin includes a plurality of photonic crystals that is configured to change a travel path of light emitted from the inorganic light emitting device.

According to an embodiment, a light refractive index of the textured transparent resin is less than a light refractive index of the inorganic light emitting device.

According to an embodiment, the inorganic light emitting device includes an electrode provided at a bottom of the inorganic light emitting device, and wherein the electrode of the inorganic light emitting device is electrically connected to the driving circuit through a bump applied on the electrode of the driving circuit.

According to an embodiment, wherein the inorganic light emitting device is configured to emit light of one color from among red, green, and blue colors.

According to an embodiment, a height of the absorber is at least 0.5 times, and no more than 1.5 times, a height of the inorganic light emitting device.

According to one or more embodiments, a method for manufacturing a display apparatus including a plurality of pixels is provided, the method including: mounting a plurality of inorganic light emitting devices, that form each pixel of the plurality of pixels, on a plurality of driving circuits which is formed on a substrate, such that the plurality of inorganic light emitting devices are electrically connected to the plurality of driving circuits, respectively; fanning an absorber between each of the plurality of inorganic light emitting devices, the absorber configured to absorb external light; forming a transparent resin on the plurality of inorganic light emitting devices; and texturing the transparent resin.

According to an embodiment, the texturing includes, by pressing a press in which a pattern is formed on a lower surface, forming the transparent resin into a textured transparent resin corresponding to the pattern.

According to an embodiment, the forming the transparent resin into the textured transparent resin includes curing the transparent resin in a state where a top surface of the transparent resin is pressed against the lower surface of the press.

According to an embodiment, the mounting further includes applying bumps to electrodes of the plurality of driving circuits, respectively; and arranging electrodes formed at bottom of the plurality of inorganic light emitting devices, on the bumps, respectively.

According to an embodiment, the forming the transparent resin includes forming the transparent resin on the absorber and on the plurality of inorganic light emitting devices.

According to an embodiment, a size of a continuous portion of the transparent resin, that is textured, on one of the plurality of inorganic light emitting devices is greater than or equal to a size of an upper surface of the one of the plurality of inorganic light emitting devices through which light emitted from the one of the plurality of inorganic light emitting devices passes.

According to an embodiment, the transparent resin that is textured includes a plurality of photonic crystals that is configured to change a travel path of light emitted from one of the plurality of inorganic light emitting devices.

According to an embodiment, a light refractive index of the transparent resin that is textured is less than a light refractive index of one of the plurality of inorganic light emitting devices.

According to one or more embodiments, a method for manufacturing a display apparatus including a plurality of pixels is provided, the method including: mounting a first inorganic light emitting device, that forms a first sub-pixel of a pixel of the plurality of pixels, on a driving circuit that is formed on a substrate, such that the first inorganic light emitting device is electrically connected to the driving circuit; forming an absorber between the first inorganic light emitting device and a second inorganic light emitting device, that is on the substrate and forms a second sub-pixel of the pixel; forming a transparent resin on the first inorganic light emitting device; and texturing the transparent resin.

According to an embodiment, the forming the transparent resin includes forming the transparent resin on the first inorganic light emitting device and the absorber.

According to an embodiment, the absorber is formed after the transparent resin is formed on the first inorganic light emitting device.

According to an embodiment, the absorber is formed after the transparent resin is formed on the first inorganic light emitting device and the transparent resin is textured.

According to an embodiment, the transparent resin is textured such that a top surface of the transparent resin is uneven.

### BRIEF DESCRIPTION OF THE DRAWINGS

The above and other aspects, features, and advantages of certain embodiments of the present disclosure will be more apparent from the following detailed description, taken in conjunction with the accompanying drawings, in which:

FIG. 1 is a diagram illustrating a display apparatus according to an embodiment.

FIG. 2A is a cross-sectional view to describe a structure of the display apparatus according to an embodiment;

FIG. 2B is a cross-sectional view to describe the structure of the display apparatus in a greater detail according to an embodiment;

FIG. 3A is a view illustrating light efficiency according to an embodiment;

FIG. 3B is a view illustrating light efficiency according to an embodiment;

FIG. 3C is a view illustrating light efficiency according to an embodiment;

FIG. 4 is a flowchart of a method for manufacturing a display apparatus according to an embodiment;

FIG. 5A is a diagram illustrating a method for manufacturing a display apparatus according to an embodiment;

FIG. 5B is a diagram illustrating the method of manufacturing the display apparatus according to the embodiment;

FIG. 5A is a view illustrating the method for manufacturing the display apparatus according to the embodiment;

FIG. 6B is a view illustrating the method for manufacturing the display apparatus according to the embodiment;

FIG. 7A is a floor plan illustrating the method for manufacturing the display apparatus according to the embodiment;

FIG. 7B is a floor plan illustrating the method for manufacturing the display apparatus according to the embodiment;

FIG. 8A is a floor plan illustrating a method for manufacturing a display apparatus according to an embodiment;

FIG. 8B is a floor plan illustrating the method for manufacturing the display apparatus according to the embodiment;

FIG. 8C is a floor plan illustrating a method for manufacturing a display apparatus according to an embodiment;

FIG. 9A is a floor plan illustrating an electronic device according to an embodiment; and

FIG. 9B is a floor plan illustrating the electronic device according to the embodiment.

### DETAILED DESCRIPTION

Embodiments of the disclosure provide a display apparatus with improved light efficiency and a method for manufacturing thereof.

In the following description of the disclosure, a detailed description of known functions and configurations incorporated herein will be omitted when it may obscure the subject matter of the disclosure. In addition, the following embodiments may be modified in many different forms, and the scope of the technical spirit of the disclosure is not limited to the following examples. Rather, these embodiments are provided so that this disclosure will be thorough and complete, and will fully convey the technical spirit to those skilled in the art.

However, it should be understood that the present disclosure is not limited to the specific embodiments described hereinafter, but includes various modifications, equivalents, and/or alternatives of the embodiments of the present disclosure. In relation to explanation of the drawings, similar drawing reference numerals may be used for similar constituent elements.

The term such as “first” and “second” used in various example embodiments may modify various elements regardless of an order and/or importance of the corresponding elements, and does not limit the corresponding elements.

In the description, the term “A or B”, “at least one of A or/and B”, or “one or more of A or/and B” may include all possible combinations of the items that are enumerated together. For example, the term “at least one of A or/and B” means (1) including at least one A, (2) including at least one B, or (3) including both at least one A and at least one B.

A singular expression includes a plural expression, unless otherwise specified. It is to be understood that the terms such as “comprise” or “include” are used herein to designate a presence of a characteristic, number, step, operation, element, component, or a combination thereof, and not to preclude a presence or a possibility of adding one or more of other characteristics, numbers, steps, operations, elements, components or a combination thereof.

The various elements and regions in the figures are drawn schematically. Accordingly, the spirit of the disclosure is not limited by the relative size or spacing depicted in the accompanying drawings.

Hereinafter, various embodiments of the disclosure will be described in greater detail with reference to the attached drawings.

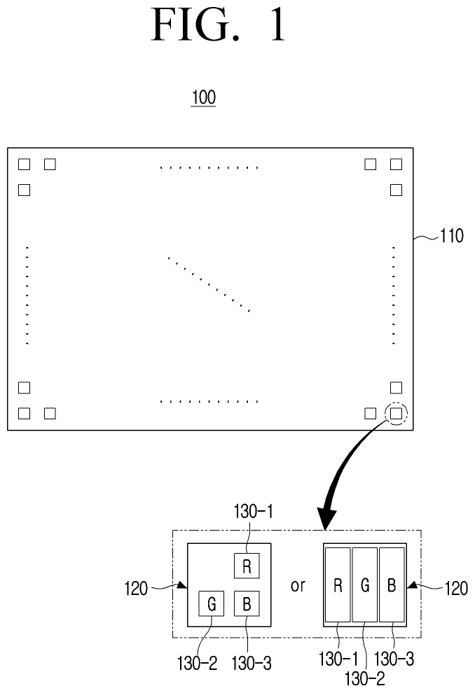

FIG. 1 is a view of a display apparatus according to an embodiment.

Referring to FIG. 1, a display apparatus 100 may include a substrate 110 and a plurality of a pixel 120. Here, the pixel 120 may refer to a minimum unit that forms an image when a light source (e.g. a micro LED) of the display apparatus 100 emits light to visually display an image. The pixel 120, on the other hand, is a pixel from among a plurality of pixels, and a description of the pixel 120 may be applied to other pixels in that the pixel 120 has the same structure and function as the other pixels of the display apparatus 100. In the following description, for convenience, it is assumed that the pixel 120 is representative of a plurality of pixels.

The display apparatus 100 is a device capable of processing an image signal received from an inside or outside storage device (not shown) and visually displaying a processed image and may be implemented as various forms such as a television (TV), a monitor, a portable multimedia device, a portable communication device, a smartphone, a smart window, a head mount display (HMD), a wearable device, a signage, or the like, and the form thereof is not limited thereto.

The substrate 110 may include a driving circuit (not shown), and may provide a space for mounting an inorganic light-emitting device. A driving circuit for driving an inorganic light-emitting device may be disposed on the substrate 110.

The substrate 110 may be implemented in a form of a small plate having a smaller height compared to width and length of the small plate, and may be implemented as a material having various properties, such as glass.

The pixel 120 may be provided in a plurality of numbers to form a matrix in a first direction (for example: width direction) and a second direction (for example: length direction) perpendicular to the first direction, the matrix of pixels may be arranged on an upper portion of the substrate 110. In this case, the matrix may have the same number of rows and columns (for example, in the case of M=N, 1×1 array, 2×2 array, etc., where M, N is a natural number). However, the number of rows and columns may be different (for example, 2×3 arrays, 3×4 arrays, etc., in the case of M≠N, where M and N are natural numbers). However, this is merely an example, and the plurality of pixels may be arranged in various forms such as diamond shapes, delta shapes, S-stripe shapes, or the like.

The pixel 120 may include a plurality of sub-pixels including a sub-pixel 130-1, a sub-pixel 130-2, and a sub-pixel 130-3. Here, each of the plurality of sub-pixels is a lower unit constituting the pixel 120, and each of the sub-pixels 130-1, 130-2, and 130-3 may include a light-emitting device (specifically, an inorganic light-emitting device). For example, the sub-pixel 130-1 may include a red light-emitting device, the sub-pixel 130-2 may include a green light-emitting device, and the sub-pixel 130-3 may include a red light-emitting device. In this case, the pixel 120 having a specific color and brightness may be configured by a combination of light emitted from each of the red light emitting device, the green light emitting device, and the blue light emitting device.

The light emitting device may include a semi-conductor light emitting device of which the width, length, and height (for example: micro LED) have a size greater than or equal to one micrometer (μm) and less than or equal to 100 micrometer.

According to an embodiment, the red light emitting device, the green light emitting device, and the blue light emitting device are not implemented as a single device included in a package, but each of the red light emitting device, the green light emitting device, and the blue light emitting device may form a sub pixel unit.

It has been described that one pixel 120 has three sub-pixels 130-1, 130-2, and 130-3 in FIG. 1 and the above-described embodiment. However, this is merely an example, and the number, arrangement, structure, color, etc. of the sub-pixels may be varied depending on various types of layouts such as a diamond format, a delta format, a stripe format, a red-green-blue-white (RGBW) format, a red-green-blue-yellow (RGBY) format, a pentile format, a quad format, a mosaic format, and the like. Accordingly, the number, arrangement, structure, and color of the inorganic light-emitting device forming the sub-pixels may also be changed in a diverse manner.

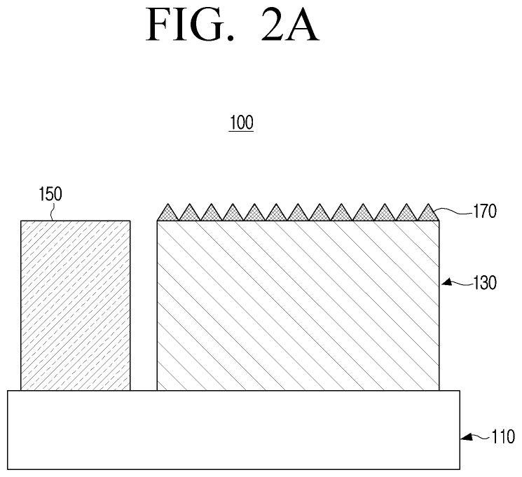

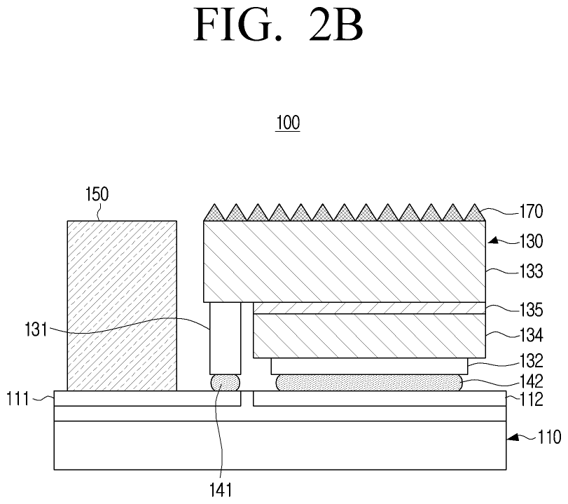

FIG. 2A is a cross-sectional view to describe a structure of a display apparatus according to an embodiment.

Referring to FIG. 2A, the display apparatus 100 may include the substrate 110, an inorganic light emitting device 130, an absorber 150, and a textured transparent resin 170.

First, the substrate 110 may be formed with a driving circuit. The driving circuit may be formed on the substrate 110 and may drive the inorganic light emitting device 130 mounted on the driving circuit. For example, the driving circuit may apply a voltage to the inorganic light emitting device 130 to emit light of a particular brightness (or gray level) or color according to a pulse width modulation (PWM), pulse amplitude modulation (PAM), or a combination thereof. Accordingly, the inorganic light emitting device 130 may be driven to display an image through the display apparatus 100.

The driving circuit may include a thin film transistor, a capacitor, or the like.

The inorganic light emitting device 130 may be formed on a driving circuit and may be included in one of the plurality of pixels.

As described above, the display apparatus 100 may include a plurality of pixels, each pixel including a plurality of light emitting devices. In this case, the inorganic light emitting device 130 may form one pixel with other inorganic light emitting devices. For example, the pixel includes a red light emitting device, a green light emitting device, and a blue light emitting device, the inorganic light emitting device 130 may be a light emitting device for emitting light of one color from among red, green, and blue.

The absorber 150 is capable of absorbing external light. For this purpose, the absorber 150 may be formed of a resin composition including, for example, a black matrix (BM), a photosensitive resin composition, or a black pigment for shielding.

Through the absorber 150, a region other than the inorganic light emitting device 130 may not be visible on the substrate 110.

In this case, the absorber 150 may be formed between the inorganic light emitting device 130 and another inorganic light emitting device included in the pixel. For example, one pixel may include a plurality of light emitting devices, and the absorber 150 may be formed between these light emitting devices.

The absorber 150 may be formed between pixels. That is, the absorber 150 may be formed on a light emitting device included in a pixel and a light emitting device included in another pixel.

The height of the absorber 150 may be a predetermined value based on the height of the inorganic light emitting device 130. For example, the height of the absorber 150 may be at least 0.5 times the height of the inorganic light emitting device 130 so that the external light absorption effect is not reduced, and may be 1.5 times or less of the height of the inorganic light emitting device 130 such that the light angle of the light emitted from the inorganic light emitting device 130 is not restricted. However, this is only one embodiment, and the height of the absorber 150 may be variously modified in consideration of a wide angle, external light absorption, or the like.

The textured transparent resin 170 may be formed on the inorganic light emitting device 130.

The textured transparent resin 170 is textured with a transparent resin, which may mean a texture (or a pattern) is formed on a surface of the transparent resin. The transparent resin may be, for example, a compound including plastic or curable resins that have a transmittance of 95% or more so that light emitted from the inorganic light emitting device 130 may be transmitted, and the texturing (that is, surface treatment or surface molding) may be easily performed.

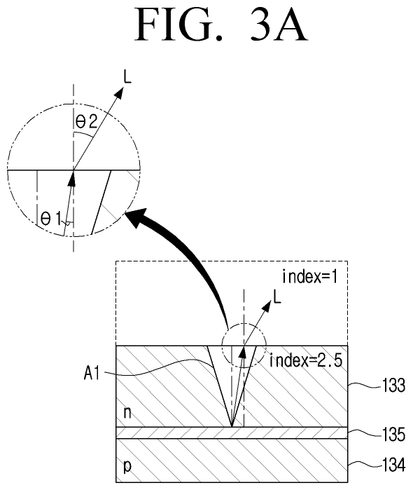

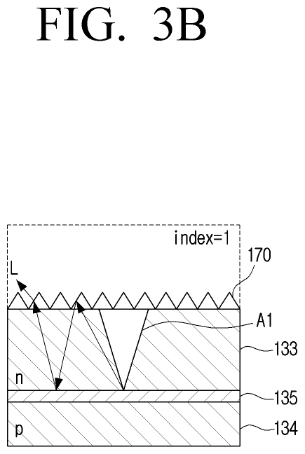

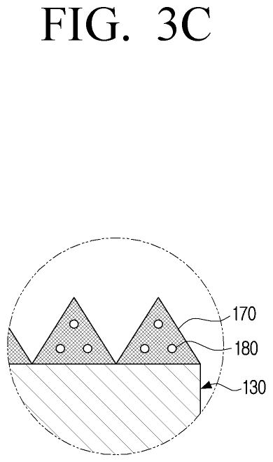

A specific description related to the textured transparent resin 170 will be described with FIGS. 3B and 3C.

FIG. 2B is a cross-sectional view to describe a structure of a display apparatus in a greater detail according to an embodiment.

In FIG. 2B, the substrate 110, the inorganic light emitting device 130, the absorber 150, and the textured transparent resin 170 are the same as described with reference to FIG. 2A, and a specific description of the overlapping portion will be omitted.

First, the substrate 110 may include a driving circuit (not shown). The driving circuit may be formed on the substrate 110, and may apply a forward voltage (e.g., a positive voltage to the p-type semiconductor, a voltage of the cathode to the n-type semiconductor) or a reverse voltage (e.g., a negative voltage to the p-type semiconductor, a voltage of the anode to the n-type semiconductor) to the inorganic light emitting device 130.

For this purpose, the driving circuit may include a first electrode 111 and a second electrode 112 that are electrically isolated (or insulated) from each other. The inorganic light emitting device 130 may include a first electrode 131 and a second electrode 132 provided at the lower portion of the inorganic light emitting device 130, and the first electrode 131 and the second electrode 132 of the inorganic light emitting device 130 may be electrically connected to the driving circuit through a bump 141 and a bump 142 applied on the first electrode 111 and the second electrode 112 of the driving circuit, respectively.

According to one embodiment, one of the first electrode 111 and the second electrode 112 may be implemented as a separate electrode for applying a separate voltage to each of the plurality of inorganic light emitting devices, and the other may be implemented as a common electrode for applying a common voltage to the plurality of inorganic light emitting devices.

The inorganic light emitting device 130 may emit light of one color from among red, green, and blue. However, this is only one embodiment, and the inorganic light emitting device 130 may emit light of other colors such as white, yellow, or the like, depending on various types of sub-pixels such as RGBW, RGBY, or the like.

The inorganic light emitting device 130 may include a first electrode 131, a second electrode 132, a first semiconductor layer 133, a second semiconductor layer 134, and an active layer (a light emitting layer) 135.

The first electrode 131 and the second electrode 132 may be formed on the lower surface of the inorganic light emitting device 130 so as to be connected to the driving circuit. That is, the inorganic light emitting device 130 according to the disclosure may have a flip-chip structure.

One of the first semiconductor layer 133 and the second semiconductor layer 134 may be an n-type semiconductor, and the other may be a p-type semiconductor. Specifically, the first semiconductor layer 133 and the second semiconductor layer 134 may be formed of various semiconductors of n-type or p-type having a band gap energy (eV) corresponding to a specific wavelength within a spectrum of light. For example, the first semiconductor layer 133 and the second semiconductor layer 134 may include at least one layer of compounds such as GaAs, GaInN, AlInGaP, AlInGaN, GaP, GaN, SiC, and sapphire (Al2O3), and may implement sub-pixels of red (R), green (G), and blue (B) by emitting light having a wavelength of red, green, and blue in the active layer 135 according to the composition and a composition ratio.

The active layer 135 may refer to a layer formed between the first semiconductor layer 133 and the second semiconductor layer 134 when the first semiconductor layer 133 and the second semiconductor layer 134 are bonded. The active layer 135 may also include one or more barrier layers having a single quantum well structure or a multi-quantum well structure (MQW).

For example, referring to FIG. 3A, if it is assumed that a forward voltage (a voltage of an anode to a p-type semiconductor and a voltage of a cathode to an n-type semiconductor) is applied to the first semiconductor layer 133 and the second semiconductor layer 134 by a driving circuit, electrons provided in the n-type semiconductor and holes provided in the p-type semiconductor may be recombined in the active layer 135 to generate photons having a specific wavelength. Hereinafter, a packet of photons will be referred to as light.

In this case, the light emitted at a particular point in the active layer 135 may be irradiated in all directions due to the omni-directional nature.

For example, when the light emitted from the inorganic light emitting device 130 travels along a path having the incident angle (θ1), the light may be refracted (or reflected or block) at a boundary between the an inside and an outside of the inorganic light emitting device 130. As an example, if the incident angle (θ1) is less than a critical angle (θc) where the range of the incident angle (θ1) is within a range of Al, the light may be refracted at a boundary of the inside and the outside of the inorganic light emitting device 130, where the light may pass (or transmit) through the interface and proceed along a path along the refraction angle (θ2). As another example, if the incident angle (θ1) of the light is greater than or equal to the critical angle (θc), the light may be reflected at the interface and proceed along a path according to the refraction angle (θ2), that is, the light may proceed to the inside of the inorganic light emitting device 130 to cause a loss of light.

Here, the incident angle (θ1) may be measured based on a normal line of the interface. In addition, the critical angle (θc) may refer to the incident angle (θ1) at which the refraction angle (θ2) of the light is 90 degrees at the interface due to the refractive index difference of a medium. For example, assuming that the refractive index of the inorganic light emitting device 130 is 2.4 and the refractive index outside the inorganic light emitting device 130 is 1, the critical angle (θc) may be about 23 degrees. In this case, a critical angle or the like may be calculated according to the principle of Snell's Law, Huygens' Principle, Fermat's Principle, Fresnel equations, or the like.

According to an embodiment, the optical efficiency may refer to a ratio between light emitting from the active layer 135 and light passed through a top surface of the inorganic light emitting device 130.

The packet of photons passing through a top surface of the inorganic light emitting device 130 is light belonging to visible rays region of red, green, and blue, and may be implemented as one sub-pixel.

Assuming that the forward voltage (a voltage of an anode to a p-type semiconductor and a voltage of a cathode to an n-type semiconductor) according to the pulse width modulation method is applied to the first semiconductor layer 133 and the second semiconductor layer 134 by the driving circuit, the intensity (or brightness) of light emitted from the active layer 135 may be varied according to the duty ratio of the pulse, and the gray scale may be expressed by adjusting the duty ratio of the pulse.

According to an embodiment, the light emitted from the active layer 135 may be irradiated in a lower surface direction as well as an upper surface direction of the inorganic light emitting device 130 due to the or omni-directional nature, and the first electrode 131 and the second electrode 132 may be implemented as a material and a structure having a high reflectivity so as to reflect light emitted from the active layer 135 in the lower surface direction toward the upper surface direction. For example, the first electrode 131 and the second electrode 132 may be formed of a metallic material such as Ag, Ti, Ni, or the like, having a high reflectivity, or a structure in which a pattern is formed on the surface.

The inorganic light emitting device 130 and the driving circuit may be connected through a bump. The bump is configured to bond the inorganic light emitting device 130 mounted on the driving circuit and electrically connect the electrode of the driving circuit and the electrode of the inorganic light emitting device 130.

At this time, the bump may be implemented as a conductive resin, and may be cured by a high temperature or low temperature heat. For example, the bump may comprise a conductive material such as one metal type (ex: Al, Cu, Sn, Au, Zn, Pb, or the like), or a mixture or alloy of at least two metal types, and the conductive material may have an average particle size of 0.1 micrometer to 10 micrometer. The bump may comprise a paste (or a material mixed with a binder resin) having adhesiveness.

As illustrated in FIG. 2B, the bump may include a bump 141 and a bump 142 according to the position where the bump is arranged. The first electrode 111 of the driving circuit and the first electrode 131 of the inorganic light emitting device 130 may be electrically connected through the bump 141 formed therebetween, and the second electrode 112 of the driving circuit and the second electrode 132 of the inorganic light emitting device 130 may be electrically connected through the bump 142 formed therebetween. The terms first electrode and second electrode are used to distinguish one from another in a pair of electrodes, and the terms are used to refer to a pair of electrodes without a special description.

With reference to FIGS. 3B to 3C, the textured transparent resin 170 will be further described.

The textured transparent resin 170 may be formed on the inorganic light emitting device 130.

In one embodiment, as shown in FIG. 3B, the textured transparent resin 170 may change the travel direction tor path) of light emitted from the inside of the inorganic light emitting device 130 to the outside by the texture formed on the surface. In this case, the interface (or surface) with respect to the inside and outside of the textured transparent resin 170 is not horizontal due to the texture, so that the angle of incidence of light at this interface may be varied. That is, in that the angle of incidence is the angle measured at the normal line of the interface, the angle of incidence of light may be reduced depending on the angle of the interface with respect to the inside and outside of the textured transparent resin 170 even though the angle at which the light travels is the same. Accordingly, even when the incident angle (θ1) of the light emitted from the inorganic light emitting device 130 is other than Al, a certain ratio of the light may be transmitted to the outside of the inorganic light emitting device 130. Compared to a case where the textured transparent resin 170 is not formed, the ratio (or light efficiency) of light transmitted from the inside of the inorganic light emitting device 130 to the outside may be increased by the textured transparent resin 170.

Here, the texture may have a height of several tens of nanometers to several micrometers, and may be formed in various structures such as a pyramid, a tooth, an uneven part, a honeycomb, a hemisphere, a polygonal cross-sectional structure, or the like. Further, the texture may be formed into a structure in which various structures are mixed, and may be formed irregularly.

In another embodiment, the light refractive index of the textured transparent resin 170 may be less than the optical refractive index (e.g., 2.5) of the inorganic light emitting device 130, and may have a value greater than the refractive index (e.g., 1) of the inorganic light emitting device 130. For example, the light refractive index of the textured transparent resin 170 may have a value of 1.5 to 1.8. Accordingly, the critical angle (θc) with respect to the interface between the inner and outer interfaces of the inorganic light emitting device 130 may increase, and the range (or limit) of the incident angle (θ1), through which light may be transmitted to the outside of the inorganic Light emitting device 130, may be increased,

The size of the textured transparent resin 170 may be greater than or equal to the size of the upper surface (or top surface) of the inorganic light emitting device 130 through which light emitted from the inorganic light emitting device 130 is able to pass. That is, the textured transparent resin 170 may be formed to cover a region where light may pass through from the upper region of the inorganic light emitting device 130.

Referring to FIG. 3C, the textured transparent resin 170 may include a plurality of photonic crystals 180 to change a travel path of light emitted from the inorganic light emitting device 130.

The photonic crystals 180 may be arranged at specific intervals (for example, between tens of nanometers and several micrometers) in a one-dimensional, two-dimensional, or three-dimensional structure. In one embodiment, the photonic crystals 180 may have a transmittance of 95% or more, and may be implemented as various materials such as materials having different refractive indices, or the like. For example, the photonic crystals 180 may be a material such as TiO₂, MgO, ZrO₂, or the like, and may have a particle diameter of several nanometers to several micrometers.

In one embodiment, the photonic crystals 180 may be arranged at regular intervals according to the wavelength or period) of light emitted from the inorganic light emitting device 130. For example, the period of the photonic crystals 180 that are arranged when the color of the light emitted from the inorganic light emitting device 130 is red may be different from the period of the photonic crystals 180 that are arranged in the case the color of the light emitted from the inorganic light emitting device 130 is green.

In the display apparatus 100 according to an embodiment as described above, the first electrode 131 and the second electrode 132 of the inorganic light emitting device 130 are located on the lower surface of the inorganic light emitting device 130 and thus, the light irradiated in a direction towards the top surface from the active layer 135 of the inorganic light emitting device 130 may be prevented from being blocked or absorbed by the electrode. In addition, the light emitted from the active layer 135 of the inorganic light emitting device 130 in the direction of the lower surface of the inorganic light emitting device 130 may be reflected to the top surface of the inorganic light emitting device 130, and the light extraction efficiency may be improved due to the refractive index difference and the texture formed on the top surface of the textured transparent resin 170.

In this case, a contrast ratio (CR), a dynamic range (DR), and a viewing angle may be improved because a plurality of light emitting devices (e.g., a red light emitting device, a green light emitting device, and a blue light emitting device) are not implemented in a single package, but each of the individual light emitting devices forms one sub-pixel unit, and an absorption layer may be formed to absorb external light between the light emitting devices compared to the case where the light emitting device is implemented in a package unit.

The pixel density may be improved because the pitch may become finer when a plurality of individualized light emitting devices are mounted. In this case, the brightness of the display apparatus 100 may be improved because more light-emitting devices may be integrated with respect to the same area. In addition, high resolution and miniaturization of the display apparatus may be implemented.

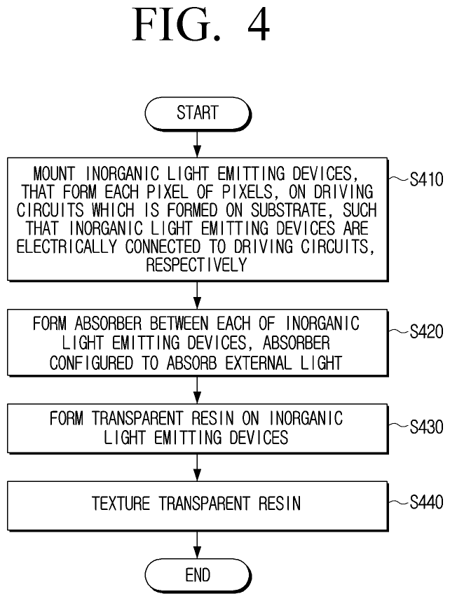

Hereinbelow, a method for manufacturing a display apparatus according to an embodiment will be described with reference to FIGS. 4 to 8C.

Referring to FIG. 4, a method for manufacturing the display apparatus 100 according to an embodiment includes the steps of mounting a plurality of inorganic light emitting devices, forming each of a plurality of pixels, on a plurality of driving circuits formed on a substrate so that the plurality of inorganic light emitting devices are electrically connected to the plurality of driving circuits formed on the substrate in operation S410; forming an absorber for absorbing external light between the plurality of inorganic light emitting devices in operation S420; forming a transparent resin on the plurality of inorganic light emitting devices in operation S430; and texturing the transparent resin in operation S440.

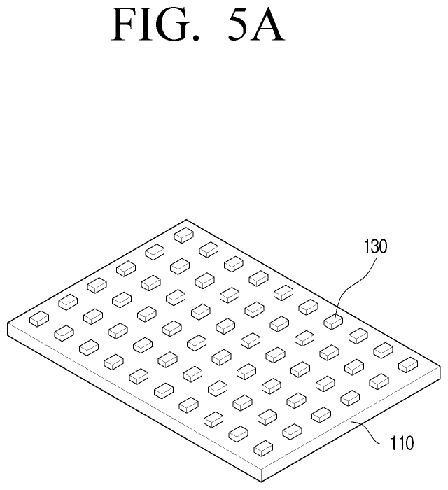

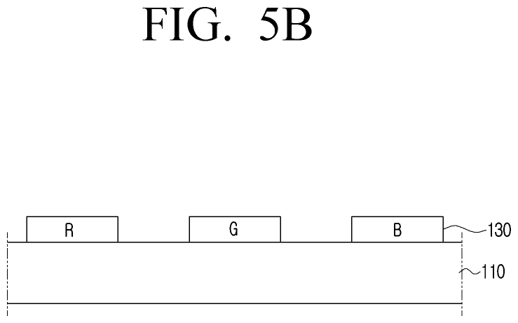

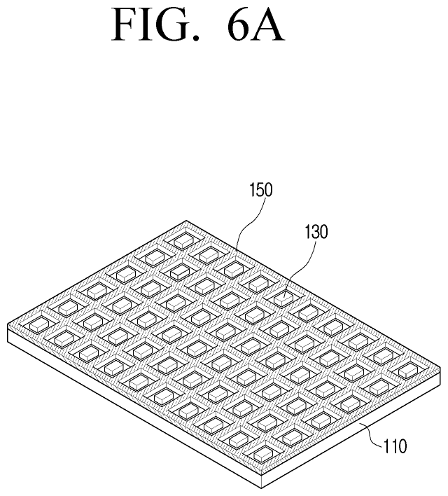

Referring to FIGS. 5A and 5B, a plurality of the inorganic light emitting device 130 may be mounted on a plurality of driving circuits in operation S410. A plurality of the inorganic light emitting device 130, each forming a respective pixel, may be mounted on a plurality of driving circuits so that the plurality of inorganic light emitting devices are electrically connected to the plurality of driving circuits formed on the substrate. FIG. 5B is a cross-sectional view of a part of a region of the structure as shown in FIG. 5A in which a plurality of inorganic light emitting devices are mounted.

For this purpose, the first electrode 111 and the second electrode 112 for connecting the driving circuit and the inorganic light emitting device 130 may be formed on a driving circuit for driving the inorganic light emitting device 130. Here, the first electrode 111 and the second electrode 112 may he conductors for electrically connecting the driving circuit and the inorganic light emitting device 130, and may be formed on the driving circuit.

In this case, the bump 141 and the bump 142 may be applied to the first electrode 111 and the second electrode 112 of the driving circuit, respectively. That is, a respective bump 141 and a respective bump 142 may be applied (or formed) on the first electrode 111 and the second electrode 112, respectively, of each driving circuit. For example, the respective bump 141 and the respective bump 142 may be applied on the first electrode 111 and the second electrode 112, respectively, of the plurality of driving circuits through various methods such as stencil printing, ball drop, laser, jet, sphere transfer, controlled collapse chip connection new process (C4NP), Au stud bumping, evaporation, electroplating, or the like. Here, the bump 141 and the bump 142 are, for bonding the inorganic light emitting device 130 mounted on the driving circuit, and electrically connecting the first electrode 111 and the second electrode 112 of the driving circuit formed on the substrate 110 with the first electrode 131 and the second electrode 132 of the inorganic light emitting device 130, and may be implemented as conductive resin, or the like.

The first electrode 131 and the second electrode 132 formed at the bottom of each of the inorganic light emitting devices may be arranged on the hump 141 and the bump 142, respectively. That is, the inorganic light emitting device 130 may be mounted on the substrate 110 in a position where the bump 141 and the bump 142 are applied on the substrate 110 so that the first electrode 111 and the second electrode 112 of the driving circuit are connected to the first electrode 131 and the second electrode 132, respectively, of the inorganic light emitting device 130. For example, as a method of mounting a single or a plurality of the inorganic light emitting device 130, an electrostatic head, X-celeprint, pick up heads, elastomer transfer printing method, or the like may be used.

In this case, the first electrode 111 and the second electrode 112 of the driving circuit and the first electrode 131 and the second electrode 132 of the inorganic light emitting device 130 may be connected to each other and bonded through the a bump 141 and a bump 142 by melting, solidifying, and then curing the bump 141 and the bump 142 through various methods such as a reflow process, a thermocompression process, or the like.

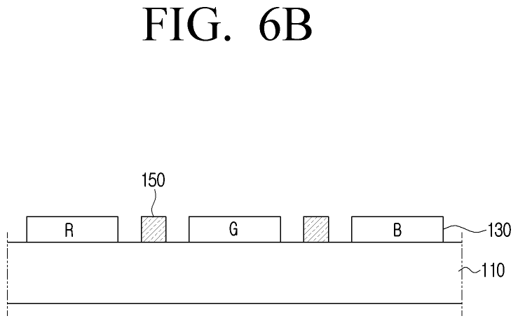

Referring to FIGS. 6A and 6B, after step S410, the absorber 150 may be formed between the plurality of the inorganic light emitting device 130 in operation S420. Here, the absorber 150 is a composition that absorbs light and exhibits a black color, and may be formed of a black matrix (BM), a photosensitive resin composition, or a resin composition including a black pigment for shielding. FIG. 6B is a cross-sectional view of a part of a region in which a plurality of inorganic light emitting devices are mounted in the structure of FIG. 6A.

The absorber 150 may be formed between the plurality of the inorganic light emitting device 130 on the substrate 110 such that a predetermined value with reference to the height of the inorganic light emitting device 130 becomes the height of the absorber 150. For example, various embodiments may be implemented such that the height of the absorber 150 may be the same as the height of the inorganic light emitting device 130, or the height becomes a value that is greater than or equal to 0.5 times the height of the inorganic light emitting device 130 and less than or equal to 1.5 times the height of the inorganic light emitting device 130.

For example, the absorber 150 may be formed between the plurality of the inorganic light emitting device 130 on the substrate 110 through the process of exposing and developing a predetermined region of the composition after applying the liquid composition to form the absorber 150 or attaching the composition in the form of a film. For example, the absorber 150 may be formed by applying (or coating) a liquid composition only between the plurality of the inorganic light emitting device 130 through an ink-jet process or the like, and then curing the applied composition. However, this is only one embodiment, and the absorber 150 may be formed through various modifications.

As an alternative to the above description, the order may be diversely modified such that the absorber 150 may be formed after the step S430 in which the transparent resin 160 is formed on the plurality of the inorganic tight emitting device 130, or after the step S440 in which the transparent resin 160 is textured.

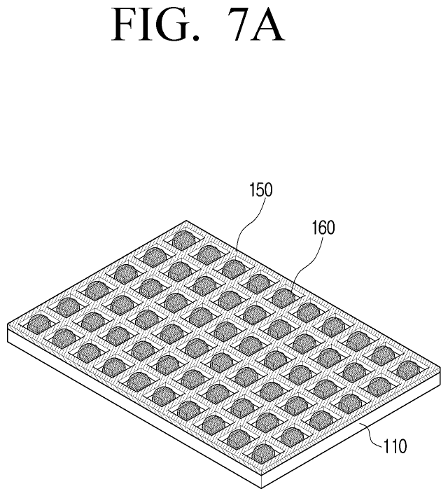

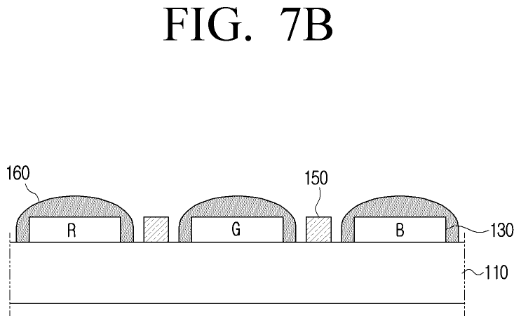

Referring to FIGS. 7A and 7B, after the step S420, the transparent resin 160 may be formed on the plurality of the inorganic light emitting device 130 in operation S430. FIG. 7B is a cross-sectional view of a part of a region in which a plurality of inorganic light emitting devices are mounted in the structure of FIG. 7A.

The size of the transparent resin 160 may be greater than or equal to the size of the top surface of the inorganic light emitting device 130 through which light emitting from the inorganic light emitting device 130 may pass.

In one embodiment, the transparent resin 160 may be applied to the plurality of the inorganic light emitting device 130 via a nozzle (not shown). For this purpose, the transparent resin 160 may be in a liquid state as a curable or plastic resin having viscosity. In this case, inkjet printing, spin coating, or the like may he used.

Thereafter, the transparent resin 150 applied on the plurality of the inorganic light emitting device 130 may be semi-cured. Here, the semi-curing state may refer to a state in which a ratio of semi-curing of the transparent resin 160 is in a predetermined range (e.g., 40% to 70%), and the shape of the transparent resin 160 may be deformed by a specific external force. In this case, an exposure, a heating process, or the like may be used.

In another embodiment, the transparent resin 160 may be attached to the plurality of the inorganic light emitting device 130 in the form of a photosensitive film, and may be formed on the plurality of the inorganic light emitting device 130 through a process of exposing and developing a specific region of the attached film.

The transparent resin 160 is formed for each of the inorganic light emitting device 130 and thus, a position wherein the transparent resin 160 is formed may correspond to the positions of the plurality of the inorganic light emitting device 130.

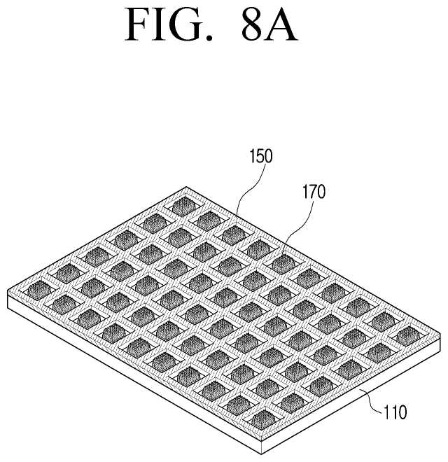

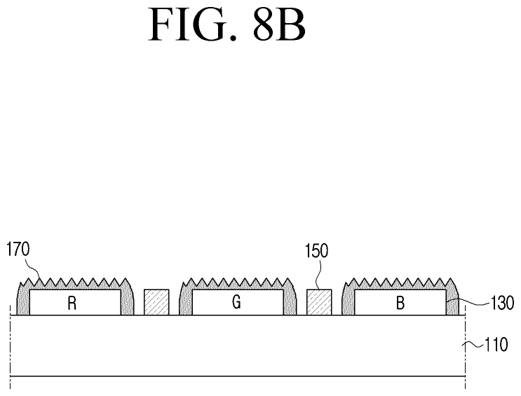

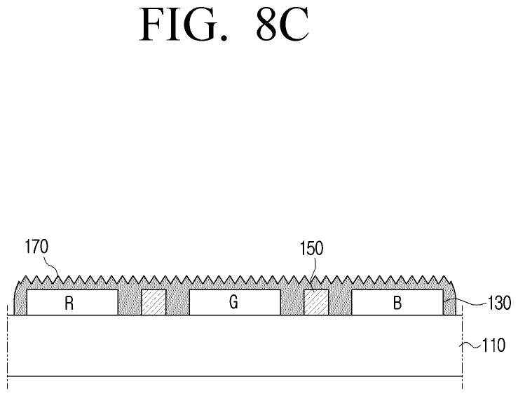

As illustrated in FIGS. 7A and 7B, the transparent resin 160 may be formed of a plurality of transparent resins that arc separated from each other such that the transparent resin 160 is not formed between each inorganic light emitting device 130. As another embodiment, as shown in FIG. 8C, a transparent resin (see textured transparent resin 170) may not be formed between the plurality of the inorganic light emitting device 130, but may be formed of one transparent resin as a whole.

Referring to FIGS. 8A and 8B, after step S430, the transparent resin 160 may be textured in operation S440. Here, the texturing may refer to forming a texture (or pattern) on the surface of the transparent resin 160. FIG. 8B is a cross-sectional view of a part of a region in which the plurality of the inorganic light emitting device 130 are mounted in the structure as shown in FIG. 8A.

In this case, of which the transparent resin 160 is formed on the inorganic light emitting device 130, the textured area may be determined based on the number of the inorganic light emitting device 130. For example, the textured region may be a region including the plurality of the inorganic light emitting device 130, or an entirety of the inorganic light emitting device 130 as a predetermined unit, based on the number of the inorganic light emitting device 130, and may be variously modified.

In one embodiment, referring to FIGS. 8A and 8B, a press (not shown) in which a pattern is formed on the lower surface of the pattern is pressed against the top surface of the transparent resin 160 (see FIGS. 7A and 7B) to form a textured transparent resin 170 corresponding to the pattern. At this time, the texture of the textured transparent resin 170 and the pattern of the press may be a relation of being intagliated or embossed. Here, the press may refer to a device that presses a plate in a vertical direction, or presses a roller in various forms, such as rotating.

Specifically, the transparent resin 160 may be cured while the lower surface of the press is pressed against the top surface of the transparent resin 160. Here, the curing may refer to a state in which the transparent resin 160 has a cured ratio greater than or equal to a predetermined value (e.g., 90%) or a state in which the shape of the transparent resin 160 is not deformed by a specific external force. In this case, an exposure, a heating process, or the like may be used.

By separating the press from the textured transparent resin 170, the display apparatus as in FIGS. 8A and 8B may be manufactured.

In another embodiment, the transparent resin 160 may be textured by applying a compound causing a chemical corrosion reaction to the transparent resin 160 through nozzle, an ink-jet, etc., to form a pattern on the top surface of the transparent resin 160, thereby texturing the transparent resin 160, or by forming a pattern on the top surface of the transparent resin 160 using mechanical friction, such as a polishing pad, thereby texturing the transparent resin 160.

The textured transparent resin 170 may further include a plurality of photonic crystals 180 for changing the traveling path of light emitted from the inorganic light emitting device 130. The photonic crystals 180 may be framed together in step S430 such that the transparent resin 160 is formed as the photonic crystals 180 are included in the transparent resin 160, or the photonic crystals 180 may be formed first eh the plurality of the inorganic light emitting device 130 through a method such as sputtering, deposition, etching, etc. before the transparent resin 160 is formed in operation S430.

As an alternative to the above-described embodiment, the forming the transparent resin 160 in step S430 may include forming the transparent resin 160 on the absorber 150 formed between each of the plurality of the inorganic light emitting device 130. In this embodiment, the transparent resin 160 may be formed at one time on the absorber 150 and the plurality of the inorganic light emitting device 130, and there is no need to remove the transparent resin 160 formed on the absorber 150, thereby simplifying the manufacturing method. Thereafter, the display apparatus 100 as shown in FIG. 8C may be manufactured through the step S440 of texturing the transparent resin 160.

As illustrated in FIGS. 8A to 8C, the display apparatus 100 manufactured according to various embodiments has been described in greater detail with reference to FIGS. 1 to 3.

The display apparatus 100 according to various embodiments may operate as a single module. That is, the display apparatus 100 may operate as one of a plurality of display apparatuses. Hereinafter, a device combined with a plurality of display apparatuses is referred to as ad electronic device 1000 for convenience.

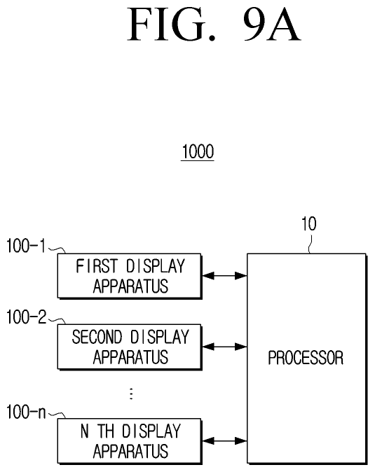

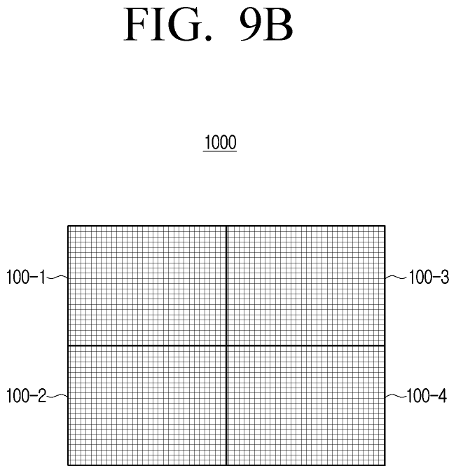

Referring to FIG. 9A, the electronic device 1000 may include a processor 10 and a plurality of display apparatuses 100-1, 100-2, . . . , 100-n.

The plurality of display apparatuses 100-1, 100-2, . . . , 100-n may each include a plurality of pixels, each pixel including a red inorganic light emitting device, a green inorganic light emitting device, and a blue inorganic light emitting device. A description of the display apparatus 100 described above may be applied to each of the plurality of display apparatuses 100-1, 100-2, . . . , 100-n, and a detailed description thereof has been described with reference to FIGS. 1 to 3.

The processor 10 may control the overall operation of the plurality of display apparatuses 100-1, 100-2, . . . , 100-n. The processor 10 may include at least one of a central processing unit (CPU), a graphics processing unit (GPU), and an application processor unit (APU).

The processor 10 may control the plurality of display apparatuses 100-1, 100-2, . . . , 100-n to display images received from external devices (not shown) or images stored in a storage device (not shown).

Specifically, the processor 10 may divide the image to correspond to the arranged positions (or coordinates) of the plurality of display apparatuses 100-1, 100-2, . . . , 100-n, and may control the plurality of display apparatuses 100-1, 100-2, . . . , 100-n to display the divided images.

For example, as shown in FIG. 9B, it is assumed that each of the plurality of display apparatuses 100-1, 100-2, 100-3, and 100-4 is arranged at an upper left end, a lower left end, a right upper end, and a right lower end, respectively.

In this case, the processor 10 may divide the image into an upper left end, a lower left end, a right upper end, and a right lower end. In addition, the processor 10 may control a display apparatus 100-1 (a first display apparatus) to display an image corresponding to the divided left upper end, control the display apparatus 100-2 (a second display apparatus) to display an image corresponding to the divided left lower end, control the display apparatus 100-3 (a third display apparatus) to display an image corresponding to the divided right upper end, and control the display apparatus 100-4 (a fourth display apparatus) to display an image corresponding to the lower end of the divided right lower end.

As described above, the processor 10 may perform control so that the plurality of display apparatuses 100-1, 100-2, 100-3, and 100-4 display an entire image.

This is merely an example, and the plurality of display apparatuses 100-1, 100-2, 100-3 and 100-4 may implement a display screen in which images having various sizes and shapes are displayed according to the number and arrangement of the display apparatuses 100-1, 100-2, . . . , 100-n.

The display apparatus 100 according, to an embodiment may include a timing controller (not shown) for controlling the inorganic light emitting device 130 of the display apparatus 100 to display an image. However, this is merely an example, and the timing controller may be provided by cabinets composed of the predetermined number of display apparatuses, and under the control of the processor 10, the timing controller may control the modular display included in each cabinet and display an image through the pixel.

According to various embodiments as described above, a display apparatus with improved light efficiency and a manufacturing method thereof may be provided.

A display apparatus with improved contrast ratio (CR) and a manufacturing method thereof may be provided.

A display apparatus with improved dynamic range (DR) and a manufacturing method thereof may be provided.

A display apparatus with improved field of view and a manufacturing method thereof may be provided.

The display module may be applied to a display apparatus such as a monitor for a personal computer (PC), a high-resolution TV, a signage, a display board, etc. through a plurality of assembly arrangements in a matrix type, and may be applied to an electronic product or an electric field requiring a wearable device, a portable device, a handheld device, and various displays in a single unit.

Various embodiments may be implemented as software that includes instructions stored in machine-readable storage media readable by a machine (e.g., a computer). A device may call instructions from a storage medium and operate in accordance with the called instructions, including an electronic apparatus (e.g., the electronic device 1000). When the instruction is executed by a processor, the processor may perform the function corresponding to the instruction, either directly or under the control of the processor, using other components.

The instructions may include a code generated by a compiler or a code executable by an interpreter. The machine-readable storage medium may be provided in the form of a non-transitory storage medium. The “non-transitory” storage medium may not include a signal and is tangible, but does not distinguish whether data is permanently or temporarily stored in a storage medium.

According to embodiments of the disclosure, a method disclosed herein may be provided in a computer program product. A computer program product may be traded between a seller and a purchaser as a commodity. A computer program product may be distributed in the form of a machine-readable storage medium (e.g., a CD-ROM) or distributed online through an application store (e.g., PlayStore™, AppStore™). In the case of on-line distribution, at least a portion of the computer program product may be stored temporarily or at least temporarily in a storage medium, such as a manufacturer's server, a server in an application store, a memory in a relay server, and the like.

Each of the components (for example, a module or a program) according to the embodiments may include one or a plurality of objects, and some subcomponents of the subcomponents described above may be omitted, or other subcomponents may be further included in the embodiments. Alternatively or additionally, some components (e.g., modules or programs) may be integrated into one entity to perform the same or similar functions performed by each respective component prior to integration. Operations performed by a module, program, or other component, in accordance with the embodiments of the disclosure, may be performed sequentially, in a parallel, repetitive, or heuristic manner, or at least some operations may be performed in a different order, omitted, or other operations may be added.

Although the disclosure has been described by way of example only, it will be understood by those skilled in the art that various changes in form and details may be made therein without departing from characteristics thereof. Further, embodiments according to the disclosure are not intended to limit the scope of the disclosure, and the scope of the disclosure is not limited by these embodiments. Accordingly, the scope of protection of the disclosure should be construed by the following claims, and all technical ideas that fall within the scope of the disclosure are to be construed as falling within the scope of the disclosure.

What is claimed is:

1. A display apparatus comprising:
a substrate on which a driving circuit is formed;
an inorganic light emitting device that is formed on the driving circuit and included in a pixel from among a plurality of pixels of the display apparatus;
an absorber that is formed between the inorganic light emitting device and another inorganic light emitting device included in the pixel, the absorber configured to absorb an external light; and
a textured transparent resin formed on the inorganic light emitting device.

2. The display apparatus of claim 1, wherein a size of the textured transparent resin is greater than or equal to a size of an upper surface of the inorganic light emitting device through which light emitted from the inorganic light emitting device passes.

3. The display apparatus of claim 1, wherein the textured transparent resin comprises a plurality of photonic crystals that is configured to change a travel path of light emitted from the inorganic light emitting device.

4. The display apparatus of claim 1, wherein a light refractive index of the textured transparent resin is less than a light refractive index of the inorganic light emitting device.

5. The display apparatus of claim 1, wherein the inorganic light emitting device comprises an electrode provided at a bottom of the inorganic light emitting device, and
wherein the electrode of the inorganic light emitting device is electrically connected to the driving circuit through a bump applied on the electrode of the driving circuit.

6. The display apparatus of claim 1, wherein the inorganic light emitting device is configured to emit light of one color from among red, green, and blue colors.

7. The display apparatus of claim 1, wherein a height of the absorber is at least 0.5 times, and no more than 1.5 times, a height of the inorganic light emitting device.

8. A method for manufacturing a display apparatus including a plurality of pixels, the method comprising:
mounting a plurality of inorganic light emitting devices, that form each pixel of the plurality of pixels, on a plurality of driving circuits which is formed on a substrate, such that the plurality of inorganic light emitting devices are electrically connected to the plurality of driving circuits, respectively;
forming an absorber between each of the plurality of inorganic light emitting devices, the absorber configured to absorb external light;
forming a transparent resin on the plurality of inorganic light emitting devices; and
texturing the transparent resin.

9. The method of claim 8, wherein the texturing comprises, by pressing a press in which a pattern is Conned on a lower surface, forming the transparent resin into a textured transparent resin corresponding to the pattern.

10. The method of claim 9, wherein the forming the transparent resin into the textured transparent resin comprises curing the transparent resin in a state where a top surface of the transparent resin is pressed against the lower surface of the press.

11. The method of claim 8, wherein the mounting further comprises:
applying bumps to electrodes of the plurality of driving circuits, respectively; and
arranging electrodes formed at bottom of the plurality of inorganic light emitting devices, on the bumps, respectively.

12. The method of claim 8, wherein the forming the transparent resin comprises forming the transparent resin on the absorber and on the plurality of inorganic light emitting devices.

13. The method of claim 8, wherein a size of a continuous portion of the transparent resin, that is textured, on one of the plurality of inorganic light emitting devices is greater than or equal to a size of an upper surface of the one of the plurality of inorganic light emitting devices through which light emitted from the one of the plurality of inorganic light emitting devices passes.

14. The method of claim 8, wherein the transparent resin that is textured comprises a plurality of photonic crystals that is configured to change a travel path of light emitted from one of the plurality of inorganic light emitting devices.

15. The method of claim 8, wherein a light refractive index of the transparent resin that is textured is less than a light refractive index of one of the plurality of inorganic light emitting devices.

16. A method for manufacturing a display apparatus including a plurality of pixels, the method comprising:
mounting a first inorganic light emitting device, that forms a first sub-pixel of a pixel of the plurality of pixels, on a driving circuit that is formed on a substrate, such that the first inorganic light emitting device is electrically connected to tire driving circuit;
forming an absorber between the first inorganic light emitting device and a second inorganic light emitting device, that is on the substrate and forms a second sub-pixel of the pixel;
forming a transparent resin on the first inorganic light emitting device; and
texturing the transparent resin.

17. The method of claim 16, wherein the forming the transparent resin comprises forming the transparent resin on the first inorganic light emitting device and the absorber.

18. The method of claim 16, wherein the absorber is formed after die transparent resin is formed on the first inorganic light emitting device.

19. The method of claim 18, wherein the absorber is formed after the transparent resin is formed on the first inorganic light emitting device and the transparent resin is textured.

20. The method of claim 16, wherein the transparent resin is textured such that a top surface of the transparent resin is uneven.
